(19) United States
(12) Patent Application Publication
(10) Pub. No.: US 2026/0347679 A1
(43) Pub. Date: Nov. 5, 2026

(54) A POLYSILOXANE COMPOSITION

(71) Applicant: Wacker Chemie AG, Munich (DE)

(72) Inventors: Liqiang ZHANG, Shanghai (CN); Haigang KANG, Shanghai (CN)

(73) Assignee: Wacker Chemie AG, Munich (DE)

(21) Appl. No.: 19/484,899

(22) PCT Filed: May 23, 2023
(86) PCT No.: PCT/CN2023/095834

§ 371 Date: Nov. 17, 2025

(51) Int. Cl. C09K 5/14; C08G 77/12; C08G 77/20; C08K 7/18

(52) U.S. Cl. CPC C09K 5/14; C08G 77/12; C08G 77/20; C08K 7/18; C08K 2201/001; C08K 2201/005

(57) ABSTRACT

A composition including a component (A), an optional component (B), a component (C) and an optional component (D). Where the component (A) is an organopolysiloxane and the optional component (B) is an organohydrogenpolysiloxane having two or more hydrogen atoms directly bonded to silicon atoms. Where the component (C) is a heat conductive filler and the optional component (D) is a platinum group metal-based curing catalyst.

### TECHNICAL FIELD

The present invention relates to the technical field of thermally conductive silicone compositions.

### BACKGROUND

CN114761492A discloses a curable silicone composition, wherein Sample 2 contains 4 kinds of spherical alumina: 35.0 parts of 120 μm, 23.6 parts of 45 μm, 26.4 parts of 2 μm and 10.5 parts of 0.5 μm. The composition has a thermal conductivity of 7.968 W/mK. The extrusion speed ER of this product is 94 g/min, and it is a product with high viscosity.

CN103059576B discloses a silicone thermal pad, which contains three kinds of alumina fillers of 3-5 μm, 40-50 μm, and 70-90 μm, wherein the mass ratio of the three particle sizes of the alumina fillers is (2-3):2:(5-7). The thermal conductivity of this product is between 4 w/mK and 5 w/mK.

CN103436019B discloses a thermally conductive gasket, which contains large particle size alumina (70-100 μm), small particle size alumina (4-6 μm), and the mass ratio of large and small particle size alumina fillers is 2:6. The thermal conductivity of this product is between 4 w/mK and 5.5 w/mK.

### SUMMARY OF INVENTION

The object of the present invention is to obtain a low-viscosity, high-thermal-conductivity composition under high filling rate.

The present invention provides a composition, which contains:
a component (A), that is an organopolysiloxane, preferably a component (A-1) that is an organopolysiloxane having two or more alkenyl groups per molecule;
optional a component (B) that is an organohydrogenpolysiloxane having two or more hydrogen atoms directly bonded to silicon atoms and is contained in such an amount that the number of moles of hydrogen atoms directly bonded to silicon atoms in the component (B) is 0.1 to 5.0 times the number of moles of alkenyl groups derived from the component (A-1);
a component (C) that is a heat conductive filler,
the component (C) contains
10-25 wt % (C-1) alumina with an average particle size greater than or equal to 0.1 μm and less than or equal to 4 μm,
for example (C-1) average particle size is 0.4, 0.6, 0.8, 1.0, 1.2, 1.4, 1.6, 1.8, 2.0, 2.2, 2.4, 2.6, 2.8 μm, content is 12 wt %, 14 wt %, 16 wt %, 18 wt %, 20 wt %, 22 wt %, 24 wt %; 20-35 wt % (C-2) alumina with an average particle size greater than or equal to 5 μm and less than or equal to 30 μm,
for example (C-2) average particle size is 6, 8, 10, 12, 14, 16, 18, 20, 22, 24, 26, 28 μm, content is 20 wt %, 22 wt %, 24 wt %, 26 wt %, 28 wt %, 30 wt %, 32 wt %, 34 wt %, 36 wt %,
50-70 wt % (C-3) alumina with an average particle size greater than or equal to 105 μm,
for example (C-3) average particle size is 110, 116, 120, 126, 130, 136, 140, 146, 150, 156, 160 μm, content is 50 wt %, 52 wt %, 54 wt %, 56 wt %, 58 wt %, 60 wt %, 62 wt %, 64 wt %,
in (C-1), (C-2) and (C-3), the total composition is calculated as 100 wt %,
optional a component (D) that is a platinum group metal-based curing catalyst having a platinum group metal element content of 0.1 to 1,000 ppm relative to the component (A-1) based on mass,
wherein the filling rate of the heat conductive filler is greater than or equal to 0.86, preferably greater than or equal to 0.90, preferably greater than or equal to 0.92, preferably greater than or equal to 0.93, preferably greater than or equal to 0.94, preferably greater than or equal to 0.95.

In the present invention, the filling rate=total heat conductive filler amount/total weight of the composition. Generally, the filling rate which is greater than or equal to 0.92 is considered as the high filling rate.

The composition as described above, wherein the total amount of all alumina is greater than 95 wt %, preferably greater than 99 wt %, more preferably greater than 99.9 wt %, and the total amount of heat conductive filler is calculated as 100 wt %.

The composition as described above, wherein the total amount of all alumina is greater than 95 wt %, preferably greater than 99 wt %, and more preferably greater than 99.9 wt %, and the total amount of fillers is calculated as 100 wt %.

The composition as described above, wherein the thermal conductivity of the composition is greater than or equal to 7.1 W/mK, preferably greater than or equal to 7.2 W/mK, more preferably greater than or equal to 7.5 W/mK.

In the composition as described above, (C-1), (C-2) and (C-3) alumina is all in spherical or quasi-spherical form.

In the composition as described above, the amount of amorphous alumina is less than 10% by weight, preferably less than 1% by weight, based on the weight of the composition as 100% by weight.

In the composition as described above, in (C-1), (C-2) and (C-3) alumina, the content of Al₂O₃ is greater than or equal to 98.1%, preferably greater than or equal to 99.1%.

The composition as described above, wherein component (C) containing
10-20 wt % (C-1) Alumina with an average particle diameter greater than or equal to 0.5 μm and less than or equal to 3 μm,
20-35 wt % (C-2) Alumina with an average particle diameter greater than or equal to 7 μm and less than or equal to 15 μm,
50-65 wt % (C-3) Alumina with an average particle diameter greater than or equal to 105 μm and less than or equal to 200 μm,
in (C-1), (C-2) and (C-3), the total composition is calculated as 100% by weight.

The composition as described above, wherein the weight ratio of (C-1)/(C-3) is between 0.15-0.40, preferably between 0.17-0.38, such as 0.19, 0.21, 0.23, 0.25, 0.27, 0.29, 0.31, 0.33, 0.35. The composition as described above, wherein the weight ratio of (C-2)/(C-3) is between 0.2 and 0.8, preferably between 0.25 and 0.75, for example 0.3, 0.4, 0.5, 0.6, 0.7.

The composition as described above, wherein the weight ratio of (C-1):(C-2):(C-3) is preferably 1:(1.5-2.5):(3.5-4.5), more preferably 1:(1.8-2.2):(3.8-4.2).

The composition as described above, wherein the ratio of (C-2)/(C-1) average particle size is between 8-18, preferably between 9-16, more preferably between 10-14, for example 10.5, 11, 11.5, 12, 12.5, 13, 13.5.

The composition as described above, wherein the ratio of (C-3)/(C-1) average particle size is between 70-250, preferably between 100-200, more preferably between 120-190, for example 125, 130, 135, 140, 145, 150, 155, 160, 165, 170, 175, 180, 185.

The composition as described above, wherein the ratio of (C-3)/(C-2) average particle size is between 7.0-20.0, preferably between 7.5-18, more preferably between 8-16, for example 8.5, 9, 10, 11, 12, 13, 14, 15.

The definition of the average particle diameter refers to the value of the cumulative average particle diameter (D50 median diameter) measured by the particle size analyzer LS 13 320 manufactured by BECKMAN COULTER on a volume basis.

(C-1) the alumina sample is prepared by the solution method. 0.1 g (C-1) sample is placed in 10 ml of absolute ethanol, dispersed by ultrasonic (100 w) and stirred for 2 minutes, so that the alumina is fully dispersed. Take out 2-3 drops of sample solution and put them into the sample cell of the particle size analyzer.

(C-2) and (C-3) alumina samples (or other heat conductive fillers with an average particle diameter greater than or equal to 7 μm) are prepared by the dry powder method, and an appropriate amount of the sample dried at room temperature is placed into the loading cylinder of the particle size analyzer. Insert the loading cylinder into the detection slot of the device.

In the present invention, the particle size distribution of (C-1), (C-2) and (C-3) alumina is unimodal, or their particle sizes meet unimodal or almost unimodal particle size distributions. The almost unimodal particle size distributions in the present invention means that in the volume integral map of the measurement sample, there might be two or more peaks, but the volume integral area of the main peak accounts for more than 80% of the entire volume integral area, preferably more than 85%, more preferably more than 90%, more preferably more than 95%.

Spherical fillers, whose outer contour is generally spherical, are filler materials which are obtained from the amorphous fillers treated by chemical and/or physical (including heat treatment) processes.

Spherical alumina is a product obtained after heat treatment of amorphous alumina, and the outer contour is generally spherical. Sphericity is 0.90 or more, preferably 0.95 or more.

Preferably, the thermal conductive silicone composition further comprises a component (E) in an amount of 1 to 100 parts by mass, preferably 1 to 50 parts by mass, preferably 1 to 10 parts by mass, relative to 100 parts by mass of the component (A).

The component (E) is any one or more selected from (E-1):
(E-1) an alkoxysilane compound shown by the following formula (1); and

R¹ₐR²_{b}Si(OR³)_{4-a-b} (1)
wherein each R¹ independently represents an alkyl group having 1 to 24 carbon atoms, preferably 6 to 24 carbon atoms, more preferably 12 to 18 carbon atoms, each
R² independently represents an unsubstituted or substituted hydrocarbon group having 1 to 10 carbon atoms, preferably methyl, ethyl, each R³ independently represents an alkyl group having 1 to 6 carbon atoms, preferably methyl, ethyl,
a represents an integer of 1 to 3, and b represents an integer of 0 to 2, provided that a+b is an integer of 1 to 3.

In the present invention, the weight ratio of component (C) to component (E-1) is between 100-800, preferably between 200-500, and more preferably between 200-400.

Additionally, it is preferred that the thermally conductive silicone composition is a two-component composition, wherein the viscosity of either component at 10 S⁻¹ 25 °C is 300 000 mPa·s or less, preferably 250 000 mPa·s or less, more preferably 230 000 mPa·s or less, more preferably 220 000 mPa·s or less.

Such a thermal conductive silicone composition is excellent in moldability.

In addition, the present invention provides a thermal conductive silicone cured product comprising a cured product of the thermal conductive silicone composition.

Such a thermal conductive silicone cured product is excellent in thermal conduction.

As described above, according to the inventive thermal conductive silicone composition, a silicone composition containing specific organopolysiloxane, hydrogenpolysiloxane, and heat conductive filler is elaborately adjusted and formulated, so that the base material is filled with the heat conductive filler at high density. This makes it possible to provide a thermal conductive silicone composition which results in a thermal conductive silicone cured product having high thermal conduction: a thermal conductivity of 7.2 W/m·K or more. Such a thermal conductive silicone cured product is useful, particularly for cooling electronic parts through thermal conduction, as a heat conducting material interposed at an interface between a thermal surface of a heat-generating electronic part and a heat dissipating member such as a heat sink or a circuit substrate.

As noted above, there have been demands for the developments of a thermal conductive silicone cured product (thermal conductive resin molded product) having high thermal conduction and good processability and a thermal conductive silicone composition for forming the cured product.

The present inventors have earnestly studied to achieve the above object and consequently found that a thermal conductive silicone cured product having high thermal conduction, such as a thermal conductivity of 7.2 W/m·K or more, can be obtained by elaborately adjusting and formulating a silicone composition containing specific organopolysiloxane, hydrogenpolysiloxane, and heat conductive filler to fill the base material with the heat conductive filler at high density. This finding has led to the completion of the present invention.

Specifically, the present invention is a thermal conductive silicone composition comprising:

Component (A): Organopolysiloxane, preferably Component (A-1): Alkenyl Group-Containing Organopolysiloxane

The component (A) is an organopolysiloxane. The component (A) serves as a main component of the inventive composition. In general, the main chain portion is normally composed of repeated basic diorganosiloxane units, but this molecular structure may partially contain a branched structure, or may be a cyclic structure. Nevertheless, the main chain is preferably linear diorganopolysiloxane from the viewpoint of physical properties of the cured product, such as mechanical strength.

The component (A-1) is an alkenyl group-containing organopolysiloxane in which the number of silicon atom-bonded alkenyl groups is at least two per molecule. The component (A-1) serves as a main component of the inventive composition. In general, the main chain portion is normally composed of repeated basic diorganosiloxane units, but this molecular structure may partially contain a branched structure, or may be a cyclic structure. Nevertheless, the main chain is preferably linear diorganopolysiloxane from the viewpoint of physical properties of the cured product, such as mechanical strength.

Functional groups bonded to a silicon atom include an unsubstituted or substituted monovalent hydrocarbon group. Examples thereof include alkyl groups, such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the functional group include ones having 1 to 10 carbon atoms, and particularly typical examples thereof include ones having 1 to 6 carbon atoms. Preferable examples of the functional group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group. Additionally, all the functional groups bonded to a silicon atom do not have to be the same.

Furthermore, the alkenyl group normally has about 2 to 8 carbon atoms. Examples thereof include a vinyl group, an allyl group, a propenyl group, an isopropenyl group, a butenyl group, a hexenyl group, a cyclohexenyl group, etc. Among these, lower alkenyl groups, such as a vinyl group and an allyl group, are preferable and a vinyl group is particularly preferable. Note that the number of the alkenyl groups has to be two or more per molecule, and the alkenyl groups are each preferably bonded to only a silicon atom at a terminal of the molecular chain to make the resulting cured product have favorable flexibility.

The component (A) organopolysiloxane has a viscosity at 25 °C in a range of preferably 10 to 100,000 mPa·s, particularly preferably 50 to 50,000 mPa·s, more preferably 50 to 20,000 mPa·s, more preferably 50 to 2,000 mPa·s, more preferably 50 to 1,000 mPa·s, more preferably 50 to 500 mPa·s, more preferably 50 to 300 mPa·s. The component (A) an organopolysiloxane is preferably a polydimethylsiloxane.

The component (A-1): Alkenyl Group-Containing Organopolysiloxane has a viscosity at 25 °C in a range of preferably 10 to 100,000 mPa·s, particularly preferably 50 to 10,000 mPa·s, more preferably 50 to 1,000 mPa·s, more preferably 50 to 200 mPa·s. When the viscosity is 10 mPa·s or more, the resulting composition has favorable storage stability. Meanwhile, when the viscosity is 100,000 mPa·s or less, the resulting composition has favorable extensibility. The component (A-1)alkenyl group-Containing Organopolysiloxane is preferably a vinyl-terminated polydimethyl-siloxane.

One kind of the organopolysiloxane of the component (A) may be used alone, or two or more kinds thereof having different viscosity or the like may be used in combination.

One kind of the alkenyl group-containing organopolysiloxane of the component (A-1) may be used alone, or two or more kinds thereof having different viscosity or the like may be used in combination.

### Optional Component (B): Organohydrogenpolysiloxane

The component (B) is an organohydrogenpolysiloxane which has at least two, preferably 2 to 100, hydrogen atoms directly bonded to silicon atoms (Si—H groups) per molecule. This component works as a crosslinking agent of the component (A-1). Specifically, a Si—H group in the component (B) is added to an alkenyl group in the component (A-1) by a hydrosilylation reaction that is promoted by a platinum group metal-based curing catalyst as the component (D) to be described later, thereby forming a three-dimensional network structure having a crosslinked structure. Note that if the number of Si—H groups per molecule in the component (B) is less than 2, no curing occurs.

The organohydrogenpolysiloxane to be used can be shown by the following average structural formula (4), but is not limited thereto.

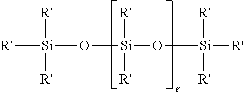

In the formula, each R′ independently represents a hydrogen atom or an unsubstituted or substituted monovalent hydrocarbon group containing no aliphatic unsaturated bond, and at least two R's are hydrogen atoms; e represents an integer of 1 or more.

Examples of the unsubstituted or substituted monovalent hydrocarbon group containing no aliphatic unsaturated bond as R′ other than hydrogen in the formula (4) include alkyl groups, such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the monovalent hydrocarbon group include ones having 1 to 10 carbon atoms, and particularly typical examples thereof include ones having 1 to 6 carbon atoms. Preferable examples of the monovalent hydrocarbon group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group. Additionally, all R's do not have to be the same.

The amount of the component (B) added is such that, relative to 1 mole of alkenyl groups derived from the component (A-1), the amount of Si—H groups derived from the component (B) is 0.1 to 5.0 moles (i.e., the number of moles of the hydrogen atoms directly bonded to silicon atoms is 0.1 to 5.0 times the number of moles of the alkenyl groups derived from the component (A-1)), preferably 0.3 to 2.0 moles, further preferably 0.5 to 1.0 moles. If the amount of the Si—H groups derived from the component (B) is less than 0.1 moles relative to 1 mole of the alkenyl groups derived from the component (A-1), no curing occurs, or the strength of the cured product is so insufficient that the molded product cannot keep the shape and cannot be handled in some cases. Meanwhile, if the amount exceeds 5.0 moles, the cured product may become inflexible and brittle.

One kind of the organopolysiloxane of the component (B) may be used alone, or two or more kinds thereof having different viscosity or the like may be used in combination.

The composition as described above, wherein component (B) could contains (B-1) and (B-2).

Component (B-1) the organic hydrogen-containing polysiloxane is an organic hydrogen-containing polysiloxane having at least 3, preferably 3-100 hydrogen atoms (Si—H groups) directly bonded to silicon atoms in one molecule, wherein the hydrogen content is between 0.5-4 mmol/g, preferably between 0.8-3 mmol/g, more preferably between 1.1-2.7 mmol/g, and more preferably between 1.5-2.3 mmol/g.

Component (B-2) the organic hydrogen-containing polysiloxane of component is an organic hydrogen-containing polysiloxane having 2 hydrogen atoms (Si—H groups) directly bonded to silicon atoms in one molecule, wherein hydrogen content is between 0.01-1.5 mmol/g, preferably between 0.1-1.2 mmol/g, more preferably between 0.3-1.0 mmol/g, more preferably between 0.4-0.8 mmol/g.

The composition as described above, wherein component (B) contains (B-1) and (B-2), and the amount of component (B-1) is between 0.5-3 wt %, preferably 1.5-2.8 wt %, based on the component (A-1) calculated as 100 wt %.

The composition as described above, wherein component (B) contains (B-1) and (B-2), and the amount of component (B-2) is between 10-50 wt %, preferably between 20-40 wt %, based on the component (A-1) calculated as 100 wt %.

### Component (C): Heat Conductive Filler

The present invention overcomes this problem of conventional techniques by elaborately adjusting and formulating a silicone composition containing specific organopolysiloxane, hydrogen-polysiloxane, and heat conductive filler to fill the base material with the heat conductive filler at high density. The present invention provides a thermal conductive silicone composition which results in a thermal conductive silicone cured product having high thermal conduction and good processability.

Preferably, the component (C) contains:
10-20 wt % (C-1) alumina having an average particle diameter of 0.1 μm or more and 3 μm or less, for example, the average particle diameter is 0.8, 1.0, 1.2, 1.4, 1.6, 1.8, 2.0, 2.2, 2.4, 2.6, 2.8 μm,
20-35 wt % (C-2) alumina having an average particle diameter of 7 μm or more and 20 μm or less, for example, the average particle diameter is 6, 8, 10, 12, 14, 16, 18 μm, and
50-65 wt % (C-3) alumina having an average particle diameter of 105 μm or more and 250 μm or less, for example, the average particle diameter is 110, 115, 120, 125, 130, 135, 140, 145, 150, 155, 160, 165, 170, 180, 190, 210, 220, 230 μm,
the amount of (C-1), (C-2) and (C-3) mentioned above is calculated based on 100% by weight of the total composition.

In this manner, particles including alumina with different particle sizes as main components are elaborately combined. Specifically, the components (C-1) small-diameter particles, (C-2) medium-diameter particles and (C-3) larger-diameter particles are combined at a carefully examined blend ratio. This enables the high-density filling in the base material in such a manner that the small-medium-diameter particles fill gaps among the larger-diameter particles. Meanwhile, if each average particle diameter of the alumina as the components (C-1), (C-2) and (C-3) is outside the ranges, or if the constituent proportions of the components (C-1), (C-2) and (C-3) are outside the ranges, these hinder the preparation of a thermal conductive silicone composition which results in a thermal conductive silicone cured product having such high thermal conduction 7.2 W/m·K or more and a relatively low viscosity.

Note that each average particle diameter is a value of volume-based cumulative average particle diameter (D50 median size) measured with a particle size analyzer LS 13 320 manufactured by BECKMAN COULTER.

The small-diameter alumina (filler) of the component (C-1) in combination with the medium-larger-diameter alumina of the component (C-2), (C-3) enhances the thermal conductivity and flowability of the composition and prevents the precipitation of the filler. The average particle diameter of the small-diameter alumina is 0.1 μm or more and less than 4 μm, preferably 0.5 to 2 μm. If the average particle diameter is outside the ranges, the effects of enhancing the thermal conductivity and flowability of the composition and preventing the filler precipitation in combination with the component (C-2), (C-3) are not obtained. One or two or more kinds of the alumina of the component (C-1) may be used as a composite.

The component (C-1) is blended in an amount of 10-25 wt %, preferably 10-23 wt %, more preferably 10-18 wt %, for example 12 wt %, 14 wt %, 16 wt %, 17 wt %, 22 wt %. The component (C-2) is blended in an amount of 22-33 wt %, preferably 23-30 wt %, more preferably 25-30 wt %, for example 22 wt %, 24 wt %, 26 wt %, 28 wt %, 32 wt %. If the mass proportion is outside the ranges, the effects of enhancing the thermal conductivity and flowability of the composition and preventing the filler precipitation attributable to the combination with the component (C-3) are not obtained.

The larger-diameter alumina (filler) of the component (C-3) enables significant enhancement of the thermal conductivity. The average particle diameter of the larger-diameter alumina is 105 μm or more and 200 μm or less, preferably 110 to 160 μm. If the average particle diameter is outside the ranges, the effect of enhancing the thermal conduction is decreased, the viscosity of the composition is increased, or the processability is lowered. One or two or more kinds of the alumina of the component (C-3) may be used as a composite.

The component (C-3) is blended in an amount of 50-65 wt %, preferably 52-68 wt %, more preferably 55-63 wt %, preferably 55-60 wt %, for example 56 wt %, 58 wt %, 62 wt %, 64 wt %. If the mass proportion is outside the ranges, the effect of enhancing the thermal conduction is decreased, the viscosity of the composition is increased, or the processability is lowered.

The amount of (C-1), (C-2) and (C-3) mentioned above is calculated based on 100% by weight of the total composition.

Thermally conductive fillers generally do not contain fumed silica or precipitated silica. In the composition of the present invention, the content of fumed silica and/or precipitated silica is less than 1 wt % preferably less than 0.1 wt %, calculated based on the total composition of 100 wt %.

The different heat conductive filler is not particularly limited. It is possible to use materials generally considered to be a heat conductive filler, for example, non-magnetic metal, such as copper or aluminum; metal oxide, such as magnesia, colcothar, beryllia, titania, or zirconia; metal nitride, such as aluminum nitride, silicon nitride, or boron nitride; metal hydroxide, such as aluminum hydroxide, magnesium hydroxide; artificial diamond, silicon carbide, etc. Additionally, the particle size of 0.1 to 200 μm may be employed. One or two or more kinds thereof may be used as a composite.

The component (C) has to be blended in an amount of 800 to 4,000 parts by mass, preferably 900 to 2,000 parts by mass, more preferably 900 to 1,500 parts by mass, relative to 100 parts by mass of the component (A). If this blend amount is less than 800 parts by mass, the resulting composition has poor thermal conductivity. If the blend amount exceeds 2,000 parts by mass, the kneading operability is impaired, and the cured product becomes significantly brittle. In order to obtain higher thermal conductivity products, the filling rate of the composition is generally greater than or equal to 0.92.

### Optional Component (D): Platinum Group Metal-Based Curing Catalyst

The component (D) is a platinum group metal-based curing catalyst and is not particularly limited, as long as the catalyst promotes an addition reaction of an alkenyl group derived from the component (A-1) and a Si—H group derived from the component (B). Examples of the catalyst include well-known catalysts used in hydrosilylation reaction. Specific examples include: platinum group metal simple substances, such as platinum (including platinum black), rhodium, and palladium; platinum chloride, chloroplatinic acid, and chloroplatinate, such as H₂PtCl₄·nH₂O, H₂PtCl₆·nH₂O, NaHPtCl₆·nH₂O, KHPtCl₆·nH₂O, Na₂PtCl₆·nH₂O, K₂PtCl₄·nH₂O, PtCl₄·nH₂O, PtCl₂, and Na₂HPtCl₄·nH₂O (here, in the formulae, n is an integer of 0 to 6, preferably 0 or 6); alcohol-modified chloroplatinic acid (see specification of U.S. Pat. No. 3,220,972); complexes of chloroplatinic acid with olefin (see U.S. Pat. No. 3,159,601 specification, U.S. Pat. No. 3,159,662 specification, and U.S. Pat. No. 3,775,452 specification); ones obtained by supporting a platinum group metal, such as platinum black and palladium, on a support, such as alumina, silica, or carbon; a rhodium-olefin complex, chlorotris(triphenylphosphine) rhodium (Wilkinson catalyst); complexes of platinum chloride, chloroplatinic acid, or chloroplatinate with a vinyl group-containing siloxane, particularly a vinyl group-no more containing cyclic siloxane; etc. The component (D) is used in such an amount that the platinum group metal element content is 0.1 to 1,000 ppm relative to the component (A-1) based on mass. If the content is less than 0.1 ppm, sufficient catalyst activity is not obtained. If the content exceeds 1,000 ppm, the cost is merely increased without enhancing the effect of promoting the addition reaction, and the catalyst remaining in the cured product may decrease the insulating property, too.

### Component (E): Surface Treatment Agent

The inventive composition can be blended with a component (E) that is a surface treatment agent in order to uniformly disperse the heat conductive filler of the component (C) in a matrix of the component (A) by hydrophobizing the heat conductive filler of the component (C) during the composition preparation to improve the wettability with the organopolysiloxane of the component (A). As the component (E), a component (E-1) and a component (E-2) described below are particularly preferable.

Component (E-1): an alkoxysilane compound shown by the following formula (1),

R¹ₐR²_{b}Si(OR³)_{4-a-b} (1)
where each R¹ independently represents an alkyl group having 1 to 24 carbon atoms, preferably 6 to 24 carbon atoms, more preferably 12 to 18 carbon atoms, each R² independently represents an unsubstituted or substituted hydrocarbon group having 1 to 10 carbon atoms, preferably methyl, ethyl, each R³ independently represents an alkyl group having 1 to 6 carbon atoms, a represents an integer of 1 to 3, and b represents an integer of 0 to 2, provided that a+b is an integer of 1 to 3.

Examples of the alkyl group represented by R¹ in the formula (1) include a hexyl group, an octyl group, a nonyl group, a decyl group, a dodecyl group, a tetradecyl group, etc. When the number of carbon atoms in the alkyl group represented by R¹ satisfies the range of 6 to 15, the wettability of the component (A) is sufficiently enhanced, resulting in excellent handleability. Moreover, the composition has favorable low temperature characteristics.

Examples of the unsubstituted or substituted hydrocarbon group represented by R² include alkyl groups, such as a methyl group, an ethyl group, a vinyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the monovalent hydrocarbon group include ones having 1 to 10 carbon atoms, and particularly typical examples thereof include ones having 1 to 6 carbon atoms. Preferable examples of the monovalent hydrocarbon group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group.

Examples of R³ include a methyl group, an ethyl group, a propyl group, a butyl group, a hexyl group, etc. Further, a and b are not particularly limited, as long as a is an integer of 1 to 3, b is an integer of 0 to 2, and a+b is an integer of 1 to 3. Preferably, a is 1 and b is 0.

The component (E-1) is preferably an alkoxysilane containing a C6-18 long-chain alkyl group; more preferably a trialkoxysilane containing a C6-18 long-chain alkyl group; more preferably hexadecyltrimethoxy silane, hexadecyltriethoxy silane, tetradecyltrimethoxy silane, tetradecyl-triethoxy silane, dodecyltrimethoxysilane, dodecyltriethoxysilane.

As the surface treatment agent of the component (E), any one or both of the component (E-1) may be blended alone or in combination. Here, the component (E) is in an amount of preferably 1 to 100 parts by mass, particularly preferably 1 to 50 parts by mass, preferably 1 to 30 parts by mass, more preferably 1 to 10 parts by mass, relative to 100 parts by mass of the component (A)

The composition as described above, wherein the amount of (E-1) is greater than 95 wt %, preferably greater than 99 wt %, more preferably greater than 99.9 wt %, calculated on the basis that the amount of all (E) component surface treatment agents is 100 wt %.

### Component (F): Property-Imparting Agent

As a component (F), it is possible to add an organopolysiloxane having a viscosity at 25 °C of to 100,000 mPa·s and shown by the following formula (3),

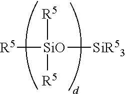

where each R⁵ independently represents a monovalent hydrocarbon group having 1 to 10 carbon atoms and no aliphatic unsaturated bond; and d represents an integer of 5 to 2,000.

The component (F) is used as appropriate in order to impart properties as a viscosity adjuster, plasticizer, and so forth for the thermal conductive silicone composition, but is not limited thereto. One kind of these may be alone, or two or more kinds thereof may be used in combination.

Each R⁵ independently represents an unsubstituted or substituted monovalent hydrocarbon group having 1 to 10 carbon atoms. Examples of R⁵ include alkyl groups, such as a methyl group, an ethyl group, a propyl group, an isopropyl group, a butyl group, an isobutyl group, a tert-butyl group, a pentyl group, a neopentyl group, a hexyl group, a heptyl group, an octyl group, a nonyl group, a decyl group, and a dodecyl group; cycloalkyl groups, such as a cyclopentyl group, a cyclohexyl group, and a cycloheptyl group; aryl groups, such as a phenyl group, a tolyl group, a xylyl group, a naphthyl group, and a biphenylyl group; aralkyl groups, such as a benzyl group, a phenylethyl group, a phenylpropyl group, and a methylbenzyl group; and groups obtained from these groups by substituting a part or all of hydrogen atoms bonded to a carbon atom(s) therein with a cyano group, a halogen atom, such as fluorine, chlorine, and bromine, or the like. Examples of such substituted groups include a chloromethyl group, a 2-bromoethyl group, a 3-chloropropyl group, a 3,3,3-trifluoropropyl group, a chlorophenyl group, a fluorophenyl group, a cyanoethyl group, a 3,3,4,4,5,5,6,6,6-nonafluorohexyl group, etc. Typical examples of the monovalent hydrocarbon group include ones having 1 to 10 carbon atoms, and particularly typical examples thereof include ones having 1 to 6 carbon atoms. Preferable examples of the monovalent hydrocarbon group include unsubstituted or substituted alkyl groups having 1 to 3 carbon atoms, such as a methyl group, an ethyl group, a propyl group, a chloromethyl group, a bromoethyl group, a 3,3,3-trifluoropropyl group, and a cyanoethyl group; and unsubstituted or substituted phenyl groups, such as a phenyl group, a chlorophenyl group, and a fluorophenyl group. A methyl group and a phenyl group are particularly preferable.

d is preferably an integer of 5 to 2,000, particularly preferably an integer of 10 to 1,000, from the viewpoint of required viscosity.

Moreover, the viscosity at 25 °C is preferably 10 to 100,000 mPa·s, particularly preferably 100 to 10,000 mPa·s. When the viscosity is 10 mPa·s or more, the cured product of the resulting composition hardly exhibits oil bleeding. When the viscosity is 100,000 mPa·s or less, the resulting thermal conductive silicone composition has suitable flexibility.

When the component (F) is added to the inventive thermal conductive silicone composition, the addition amount is not particularly limited, could be 10 to 100 parts by mass relative to 100 parts by mass of the component (A). When the addition amount is in this range, this makes it easy to maintain the favorable flowability and operability of the thermal conductive silicone composition before curing, and to fill the composition with the heat conductive filler of the component (C).

In the inventive thermal conductive silicone composition, the dosage of the component (F) is preferably lower than 0.1 parts by mass, more preferably lower than 0.01 parts by mass, relative to 100 parts by mass of the component (A). In this way, it is possible to avoid oil leakage and contamination of the substrate of the thermally conductive silicone composition.

### Optional Component (G): Reaction Inhibitor

As a component (G), an addition reaction inhibitor is usable. As the addition reaction inhibitor, any of known addition reaction inhibitors used in usual addition reaction-curable silicone compositions can be employed. Examples thereof include acetylene compounds, such as 1-ethynyl-1-hexanol and 3-butyn-1-ol, various nitrogen compounds, organophosphorus compounds, oxime compounds, organochlorine compounds, etc. When the component (G) is blended, the use amount is preferably 0.01 to 1 parts by mass, more preferably 0.1 to 0.8 parts by mass, relative to 100 parts by mass of the component (A-1). With such a blend amount, the curing reaction proceeds sufficiently, and the molding efficiency is not impaired.

### Other Components

The inventive thermal conductive silicone composition may be further blended with other component(s), as necessary. Examples of the blendable optional components include heat resistance improvers, such as iron oxide and cerium oxide; viscosity adjusters, such as silica; colorants; release agents; etc.

### EMBODIMENTS

### Thermal Conductive Silicone Cured Product, and Production Method Therefor

A thermal conductive silicone cured product (thermally-conductive resin molded product) according to the present invention is a cured product of the above-described thermal conductive silicone composition. The curing conditions of curing (molding) the thermal conductive silicone composition may be the same as those for known addition reaction-curable silicone rubber compositions. For example, the thermal conductive silicone composition is sufficiently cured at normal temperature, too, but may be heated as necessary. Preferably, the thermal conductive silicone composition is subjected to addition curing at 100 to 120 °C for 8 to 12 minutes or preferably curing within 7 days at room temperature; or preferably curing within 1 day at room temperature. Such a cured product (molded product) of the present invention is excellent in thermal conduction.

### Thermal Conductivity of Molded Product

The inventive molded product has a thermal conductivity of preferably 7.2 W/m·K or more, which is a measurement value measured at 25 °C. The product having a thermal conductivity of 7.2 W/m·K or more is applicable to heat-generating members which generate large amounts of heat. Note that such a thermal conductivity can be adjusted by coordinating the type of the heat conductive filler or combination of the particle sizes.

### Hardness of Molded Product

The inventive molded product is tested by a Zwick hardness tester. Note that such a hardness can be adjusted by changing the proportions of the component (A-1) and the component (B) to adjust the crosslinking density.

According to DIN53019, an Anton Paar MCR302 instrument was used to test the kinematic viscosity and static viscosity of the composition of the present invention.

Components (A) to (G) used in the following Examples and Comparative Examples are shown below.

### Component (A):

(A-1) Component, an organopolysiloxane shown by the following formula (5), wherein X represents a vinyl group, and n represents the number resulting in the viscosity of 120 mPa·s.

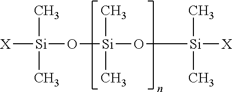

### Component (B):

(B-1) a side chain hydrogenpolysiloxane shown by the following formula (6), the hydrogen content is 1.7 mmol/g.

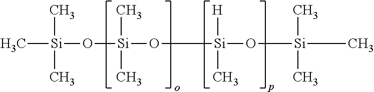

(B-2) a terminated hydrogenpolysiloxane shown by the following formula (5), wherein X represents hydrogen. The hydrogen content is 0.53 mmol/g.

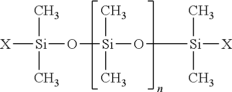

### Component (C):

(C-1) quasi-spherical alumina with an average particle diameter of 0.8 μm
(C-2) spherical alumina with an average particle diameter of 10 μm
(C-3-1) spherical alumina with an average particle diameter of 120 μm
(C-3-1) spherical alumina with an average particle diameter of 150 μm
(C-4) spherical alumina with an average particle diameter of 90 μm

### Component (D):

a 2-ethyl hexanol solution of 5 wt % of chloroplatinic acid

### Component (E):

Cetyltrimethoxysilane

### Component (G):

Ethynyl cyclohexanol as an addition reaction inhibitor.

The above-mentioned materials are provided by Wacker Chemie AG.

The components were added in predetermined amounts shown later under Examples and Comparative Examples in Table 1 and kneaded with a planetary mixer for 60 minutes.

### Molding Method

After mixture, the compositions in Table 1 are obtained.

The obtained compositions in Table 1 were each poured into a mold with a size of 60 mm×60 mm×6 mm and molded using a press molding machine at 100 °C for 60 minutes.

### Evaluation Methods Thermal Conductivity:

Under conditions of 100 °C and 60 minutes, the compositions obtained in the following Examples and Comparative Examples in Table 1 were cured into sheet form with a thickness of 2 mm, 4 mm, and 6 mm. Sheets from each composition were used to measure the thermal conductivity at 50 °C with a thermal conductivity meter TIM tester 1300-1400 according to ASTM 5470.

### Hardness:

The compositions obtained in the following Examples and Comparative Examples were cured into sheet form with a thickness of 6 mm as described above. Two sheets from each composition were stacked on each other and measured by a Zwick hardness tester to get a Shore00 value.

TABLE 1
Thermally conductive caulk composition

| | C. Ex. 1 | C. Ex. 2 | C. Ex. 3 | Ex. 4 | Ex. 5 | Ex. 6 |
|---|---|---|---|---|---|---|
| A component | | | | | | |
| (A-1) | 4.55 | 4.55 | 4.55 | 4.55 | 4.55 | 4.55 |
| (C-1) | 13 | 13.57 | 13 | 13 | 13.57 | 13.57 |
| (C-2) | 37 | 27.14 | 37 | 22 | 27.14 | 27.14 |
| (C-3-1) | 45 | | | 60 | | 54.29 |
| (C-3-2) | | | | | 54.29 | |
| (C-4) | | 54.29 | 45 | | | |
| (D) | 0.1 | 0.1 | 0.1 | 0.1 | 0.1 | 0.1 |
| (E) | 0.3 | 0.3 | 0.3 | 0.3 | 0.3 | 0.3 |
| Total amount | 100 | 100 | 100 | 100 | 100 | 100 |
| filling rate | 0.95 | 0.95 | 0.95 | 0.95 | 0.95 | 0.95 |
| 10 S⁻¹ mPa · s | 263900 | 235100 | 290900 | 216000 | 193100 | 212900 |
| B component | | | | | | |
| (A-1) | 2.95 | 2.95 | 2.95 | 2.95 | 2.95 | 2.95 |
| (B-1) | 0.1 | 0.1 | 0.1 | 0.1 | 0.1 | 0.1 |
| (B-2) | 1.45 | 1.45 | 1.45 | 1.45 | 1.45 | 1.45 |
| (C-1) | 13 | 13.57 | 13 | 13 | 13.57 | 13.57 |
| (C-2) | 37 | 27.14 | 37 | 22 | 27.14 | 27.14 |
| (C-3-1) | 45 | | | 60 | | 54.29 |
| (C-3-2) | | | | | 54.29 | |
| (C-4) | | 54.29 | 45 | | | |
| (E) | 0.3 | 0.3 | 0.3 | 0.3 | 0.3 | 0.3 |
| (G) | 0.2 | 0.2 | 0.2 | 0.2 | 0.2 | 0.2 |
| Total amount | 100 | 100 | 100 | 100 | 100 | 100 |
| filling rate | 0.95 | 0.95 | 0.95 | 0.95 | 0.95 | 0.95 |
| 10 S⁻¹ mPa · s | 252400 | 235200 | 251800 | 207200 | 197900 | 181300 |

TABLE 2
Thermally conductivity

| | C. Ex. 1 | C. Ex. 2 | C. Ex. 3 | Ex. 4 | Ex. 5 | Ex. 6 |
|---|---|---|---|---|---|---|
| Thermally | 7.02 | 6.41 | 6.1 | 7.68 | 8.03 | 7.8 |
| conductivity | | | | | | |
| w/mK | | | | | | |

In Table. 1,

In the case of the same type of alumina with small, medium and large particle sizes, C.Ex.1 which the amount of large particle size is low is compared with Ex.6. The obtained composition in C.Ex. 1 has high viscosity and low thermal conductivity.

In the case of the same proportion of alumina with small, medium and large particle sizes, it can be seen from the comparison of C.Ex.2 and Ex.6 that the composition obtained in C.Ex.2 (using alumina with an average particle size of 90 μm), has higher viscosity and lower thermal conductivity.

When the types and amounts of alumina with small, medium and large particle sizes are not within the appropriate range, C.Ex.3 has the highest viscosity and the lowest thermal conductivity.

The product obtained in Ex.6 has low viscosity, high thermal conductivity, Shore 00 hardness of 60, and suitable elasticity.

1-9. (canceled)

10. A composition, comprising:
a component (A), that is an organopolysiloxane, preferably a component (A-1) that is an organopolysiloxane having two or more alkenyl groups per molecule;
an optional component (B) that is an organohydrogenpolysiloxane having two or more hydrogen atoms directly bonded to silicon atoms and is contained in such an amount that the number of moles of hydrogen atoms directly bonded to silicon atoms in the component (B) is 0.1 to 5.0 times the number of moles of alkenyl groups derived from the component (A-1);
a component (C) that is a heat conductive filler;
wherein the component (C) comprises 10-25 wt % (C-1) alumina with an average particle size greater than or equal to 0.1 μm and less than or equal to 4 μm, 20-35 wt % (C-2) alumina with an average particle size greater than or equal to 5 μm and less than or equal to 30 μm, 50-70 wt % (C-3) alumina with an average particle size greater than or equal to 146 μm, and wherein (C-1), (C-2) and (C-3), the total composition is calculated as 100 wt %;
an optional component (D) that is a platinum group metal-based curing catalyst having a platinum group metal element content of 0.1 to 1,000 ppm relative to the component (A-1) based on mass; and
wherein the filling rate of the heat conductive filler is greater than or equal to 0.86, preferably greater than or equal to 0.90, preferably greater than or equal to 0.92, preferably greater than or equal to 0.93, preferably greater than or equal to 0.94, preferably greater than or equal to 0.95.

11. The composition of claim 10, wherein the total amount of all the alumina is greater than 95 wt %, preferably greater than 99 wt %, and more preferably greater than 99.9 wt %, and the total amount of fillers is calculated as 100 wt %.

12. The composition of claim 10, wherein the thermal conductivity of the composition is greater than or equal to 7.1 W/mK, preferably greater than or equal to 7.2 W/mK, more preferably greater than or equal to 7.5 W/mK.

13. The composition of claim 10, wherein component (C) comprises
10-20 wt % (C-1) Alumina with an average particle diameter greater than or equal to 0.5 μm and less than or equal to 3 μm,
20-35 wt % (C-2) Alumina with an average particle diameter greater than or equal to 7 μm and less than or equal to 15 μm, and
50-65 wt % (C-3) Alumina with an average particle diameter greater than or equal to 105 μm and less than or equal to 200 μm, wherein (C-1), (C-2) and (C-3), the total composition is calculated as 100% by weight.

14. The composition of claim 10, wherein the weight ratio of (C-2)/(C-3) is between 0.2 and 0.8, preferably between 0.25 and 0.75.

15. The composition of claim 10, wherein the weight ratio of (C-1):(C-2):(C-3) is preferably 1:(1.5-2.5):(3.5-4.5), more preferably 1:(1.8-2.2):(3.8-4.2).

16. The composition of claim 10, wherein the ratio of (C-3)/(C-1) average particle size is between 70-250, preferably between 100-200, more preferably between 120-190.

17. The composition of claim 10, wherein the ratio of (C-3)/(C-2) average particle size is between 7.0-20.0, preferably between 7.5-18, more preferably between 8-16.

18. The composition of claim 10, wherein the composition is a two-component composition, wherein the viscosity of either component at 10 S⁻¹ 25 °C is 300 000 mPa·s or less, preferably 250 000 mPa·s or less, more preferably 230 000 mPa·s or less, more preferably 220 000 mPa·s or less.
